(19) United States
(12) Patent Application Publication
(10) Pub. No.: US 2024/0282901 A1
(43) Pub. Date: Aug. 22, 2024

(54) SEMICONDUCTOR LIGHT-EMITTING ELEMENT, LIGHT-EMITTING MODULE, AND METHOD FOR MANUFACTURING LIGHT-EMITTING MODULE

(71) Applicant: Nuvoton Technology Corporation Japan, Kyoto (JP)

(72) Inventors: Shuichi NAKAZAWA, Toyama (JP); Masanori HIROKI, Shiga (JP); Shigeo HAYASHI, Kyoto (JP)

(21) Appl. No.: 18/653,508

(22) Filed: May 2, 2024

Related U.S. Application Data
(63) Continuation of application No. PCT/JP2022/040764, filed on Oct. 31, 2022.

(30) Foreign Application Priority Data
Nov. 10, 2021 (JP) 2021-183532

(51) Int. Cl. H01L 33/62; H01L 33/00

(52) U.S. Cl. CPC H01L 33/62; H01L 33/007; H01L 2933/0066

(57) ABSTRACT

A semiconductor light-emitting element includes: a semiconductor stack; a contact electrode disposed above the semiconductor stack; and a pad layer disposed above the contact electrode and containing Au. The pad layer includes a first layer disposed above a region in which the pad layer and the contact electrode are in contact with each other, and a second layer disposed above the first layer and in contact with the first layer. In a direction parallel to a principal surface of the contact electrode, a mean grain size of Au in the second layer is larger than a mean grain size of Au in the first layer.

### CROSS REFERENCE TO RELATED APPLICATIONS

This is a continuation application of PCT International Application No. PCT/JP2022/040764 filed on Oct. 31, 2022, designating the United States of America, which is based on and claims priority of Japanese Patent Application No. 2021-183532 filed on Nov. 10, 2021. The entire disclosures of the above-identified applications, including the specifications, drawings and claims are incorporated herein by reference in their entirety.

### FIELD

The present disclosure relates to a semiconductor light-emitting element, a light-emitting module, and a method for manufacturing the light-emitting module.

### BACKGROUND

Semiconductor light-emitting elements such as semiconductor laser elements have been conventionally known. In such semiconductor light-emitting elements, an increase in efficiency and a reduction in heat generation are in demand. For example, in the semiconductor laser element disclosed by Patent Literature (PTL) 1, gold (hereinafter, referred to as Au) having good electrical conductivity is used in a pad electrode to be disposed on the p-side electrode. In this way, the semiconductor laser element disclosed by PTL 1 intends to achieve an increase in efficiency and a reduction in heat generation.

### CITATION LIST

### Patent Literature

PTL 1: International Publication No. 2020/110783

### SUMMARY

### Technical Problem

However, even though Au is used in a pad electrode in the same manner as the semiconductor laser element disclosed by PTL 1, the electrical resistance of the semiconductor laser element can be improved upon. For example, when a pad electrode and a submount are joined together using AuSn solder in the same manner as the semiconductor laser element disclosed by PTL 1, tin (hereinafter, referred to as Sn) diffuses up to a p-side electrode via the pad electrode. This may result in an increase in the contact resistance between a semiconductor layer and the p-side electrode.

The present disclosure addresses the above-described problem, and aims to provide a semiconductor light-emitting element, etc., that include an electrode with a reduced electrical resistance.

### Solution to Problem

In order to address the above-described problem, a semiconductor light-emitting element according to one aspect of the present disclosure includes: a semiconductor stack; a contact electrode disposed above the semiconductor stack; and a pad layer disposed above the contact electrode and containing Au. The pad layer includes: a first layer disposed above a region in which the pad layer and the contact electrode are in contact with each other; and a second layer disposed above the first layer and in contact with the first layer. In a direction parallel to a principal surface of the contact electrode, a mean grain size of Au in the second layer is larger than a mean grain size of Au in the first layer.

A light-emitting module according to one aspect of the present disclosure includes: a semiconductor light-emitting element; and a base to which the semiconductor light-emitting element is joined. The semiconductor light-emitting element includes: a semiconductor stack; a contact electrode disposed between the semiconductor stack and the base; a joining layer disposed between the contact electrode and the base, and containing AuSn; and an insulating layer disposed between the semiconductor stack and the joining layer. The joining layer includes an outer joining region disposed in a position facing the insulating layer. An average Sn content in a center in a thickness direction of the outer joining region is lower than an average Sn content in both end portions in the thickness direction of the outer joining region.

A method for manufacturing a light-emitting module according to one aspect of the present disclosure includes: preparing a semiconductor light-emitting element and a base; and joining the semiconductor light-emitting element to the base, using a joining material containing AuSn. The semiconductor light-emitting element includes: a semiconductor stack; a contact electrode disposed above the semiconductor stack; and a pad layer electrically connected with the contact electrode, disposed above the contact electrode, and containing Au. The pad layer includes: a first layer disposed above a region in which the pad layer and the contact electrode are in contact with each other; and a second layer disposed above the first layer and in contact with the first layer. A crystal grain of Au in the second layer is columnar. In a direction parallel to a principal surface of the contact electrode, a mean grain size of the Au in the second layer is larger than a mean grain size of Au in the first layer. In the joining, the joining material joins the base and the pad layer together.

### Advantageous Effects

The present disclosure can provide a semiconductor light-emitting element, etc., that include an electrode with a reduced electrical resistance.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic plan view of the overall configuration of a semiconductor light-emitting element according to Embodiment 1.

FIG. 2 is a schematic cross-sectional view of the overall configuration of the semiconductor light-emitting element according to Embodiment 1.

FIG. 3 is a transmission electron microscope (TEM) image showing shapes of crystal grains in a contact region according to Embodiment 1.

FIG. 4 is a diagram illustrating the shapes of crystal grains in the contact region according to Embodiment 1.

FIG. 5 is a diagram illustrating one example of a current supply mode of the semiconductor light-emitting element according to Embodiment 1.

FIG. 6 is a diagram illustrating an overview of current paths in a pad layer of a semiconductor light-emitting element according to a comparative example.

FIG. 7 is a diagram illustrating an overview of current paths in a pad layer according to Embodiment 1.

FIG. 8 is a diagram illustrating a method for measuring the mean grain size.

FIG. 9 is a cross-sectional view showing the first process of a method for manufacturing the semiconductor light-emitting element according to Embodiment 1.

FIG. 10 is a cross-sectional view showing the second process of the method for manufacturing the semiconductor light-emitting element according to Embodiment 1.

FIG. 11 is a cross-sectional view showing the third process of the method for manufacturing the semiconductor light-emitting element according to Embodiment 1.

FIG. 12 is a cross-sectional view showing the fourth process of the method for manufacturing the semiconductor light-emitting element according to Embodiment 1.

FIG. 13 is a cross-sectional view showing the fifth process of the method for manufacturing the semiconductor light-emitting element according to Embodiment 1.

FIG. 14 is a cross-sectional view showing the sixth process of the method for manufacturing the semiconductor light-emitting element according to Embodiment 1.

FIG. 15 is a cross-sectional view showing the seventh process of the method for manufacturing the semiconductor light-emitting element according to Embodiment 1.

FIG. 16 is a cross-sectional view showing the eighth process of the method for manufacturing the semiconductor light-emitting element according to Embodiment 1.

FIG. 17 is a schematic cross-sectional view of the overall configuration of a light-emitting module according to Embodiment 2.

FIG. 18 is a flowchart showing a method for manufacturing the light-emitting module according to Embodiment 2.

FIG. 19 is a schematic cross-sectional view showing the preparation process of preparing the light-emitting module according to Embodiment 2.

FIG. 20 is a graph showing the Sn intensity distribution in a first joining region according to Embodiment 2, which is obtained by carrying out energy-dispersive X-ray spectroscopy (EDX) analysis on the straight line along the thickness direction of the first joining region.

FIG. 21 is a graph showing the Sn intensity distribution in a second joining region according to Embodiment 2, which is obtained by carrying out the EDX analysis on the straight line along the thickness direction of the second joining region.

FIG. 22 is a graph showing the average Sn intensity distribution in the first joining region according to Embodiment 2, which is obtained by carrying out the EDX analysis in a region along the thickness direction of the first joining region.

FIG. 23 is a graph showing the average Sn intensity distribution in the second joining region according to Embodiment 2, which is obtained by carrying out the EDX analysis on the region along the thickness direction of the second joining region.

### DESCRIPTION OF EMBODIMENTS

Hereinafter, embodiments according to the present disclosure will be described with reference to the drawings. Note that the embodiments described below each show a specific example of the present disclosure. The numerical values, shapes, materials, elements, the arrangement and connection of the elements, etc., in the following embodiments are mere examples, and therefore do not intend to limit the present disclosure.

Moreover, the drawings each are a schematic diagram, and do not necessarily provide strictly accurate illustration. Accordingly, the drawings do not necessarily agree with one another in terms of scales and the like. Throughout the drawings, the same reference mark is given to substantially the same structural element, and redundant description is omitted or simplified.

Moreover, in the present specification, the terms “upper/above” and “lower/below” do not refer to the vertically upward direction and vertically downward direction in terms of absolute spatial recognition, but are used as terms defined by relative positional relationships based on the stacked order in a stacked configuration. In addition, the terms “upper/above” and “lower/below” are applied not only when two elements are disposed spaced apart with another element interposed therebetween, but also when the two elements are disposed in contact with each other.

### Embodiment 1

A semiconductor light-emitting element according to Embodiment 1 will be described.

### 1-1. Overall Configuration

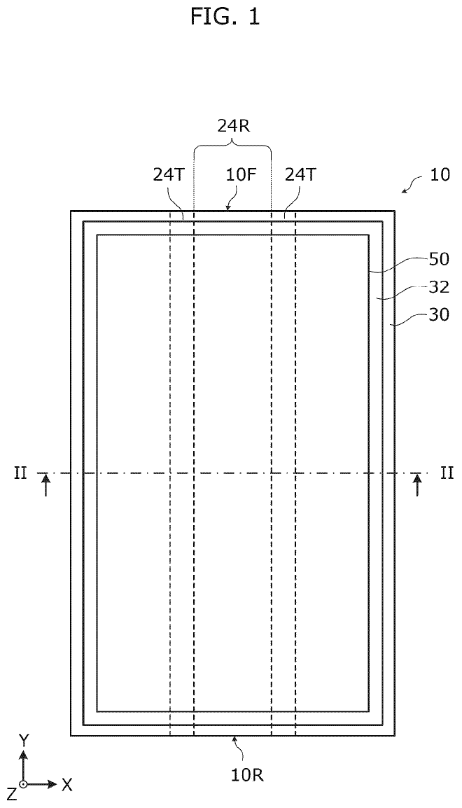

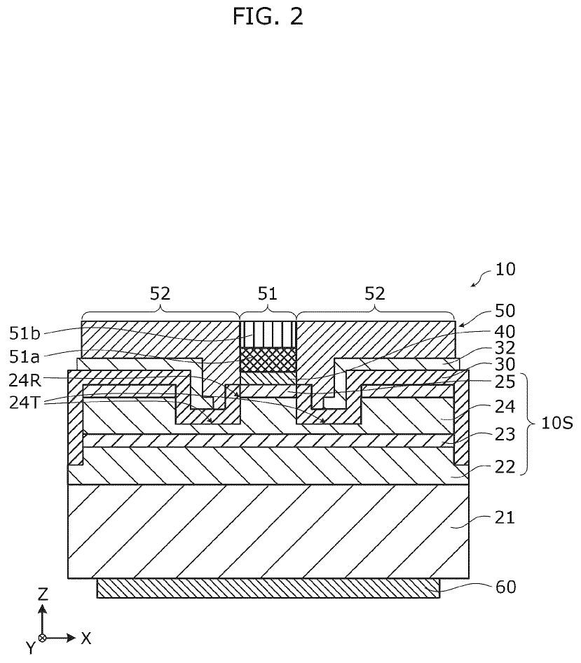

First, an overall configuration of the semiconductor light-emitting element according to the present embodiment will be described with reference to FIG. 1 and FIG. 2. FIG. 1 and FIG. 2 are a schematic plan view and a schematic cross-sectional view, respectively, showing the overall configuration of semiconductor light-emitting element 10 according to the present embodiment. FIG. 2 illustrates a cross-section taken along line II-II shown in FIG. 1. Note that each of the diagrams shows the X axis, Y axis, and Z axis that are orthogonal to each other. These X-, Y-, and Z-axes are axes of the right-handed orthogonal coordinate system. The stacked direction of semiconductor light-emitting element 10 is parallel to the Z-axis direction, and the main direction toward which light (laser light in the present embodiment) is emitted is parallel to the Y-axis direction.

As illustrated in FIG. 2, semiconductor light-emitting element 10 includes semiconductor stack 10S, and emits light from end face 10F (see FIG. 1) in the direction perpendicular to the stacked direction (i.e., the Z-axis direction) of semiconductor stack 10S. In the present embodiment, semiconductor light-emitting element 10 is a nitride semiconductor laser element including two end faces 10F and 10R that form a resonator. End face 10F is the front-end face from which laser light is emitted, and end face 10R is the rear-end face that is more reflective than end face 10F. In the present embodiment, the reflectance of end face 10F and the reflectance of end face 10R are 6% and 98% , respectively. Semiconductor light-emitting element 10 also includes a waveguide formed between end face 10F and end face 10R. The resonator length (i.e., the distance between end face 10F and end face 10R) of semiconductor light-emitting element 10 according to the present embodiment is approximately 1000 μm. Semiconductor light-emitting element 10 emits, for example, blue-violet light whose peak wavelength is in the band of 405 nm.

As illustrated in FIG. 2, semiconductor light-emitting element 10 includes substrate 21, semiconductor stack 10S, insulating layer 30, adhesion support layer 32, contact electrode 40, pad layer 50, and N-side electrode 60.

Substrate 21 is a plate-shaped member that serves as the base of semiconductor light-emitting element 10. In the present embodiment, substrate 21 is an N-type GaN substrate.

Semiconductor stack 10S is a stack including nitride semiconductors. Semiconductor stack 10S includes a plurality of semiconductor layers stacked in the stacked direction (i.e., the Z-axis direction in each diagram). In the present embodiment, semiconductor stack 10S includes N-side semiconductor layer 22, active layer 23, P-side semiconductor layer 24, and contact layer 25.

N-side semiconductor layer 22 is one example of a first semiconductor layer of the first conductivity type which is disposed above substrate 21 and below active layer 23. N-side semiconductor layer 22 includes a nitride semiconductor. In the present embodiment, N-side semiconductor layer 22 includes an N-type cladding layer having a refractive index lower than the refractive index of active layer 23. N-side semiconductor layer 22 is, for example, an N-type AlGaN layer. Note that N-side semiconductor layer 22 may include a layer other than the N-type cladding layer. N-side semiconductor layer 22 may include, for example, a buffer layer, a light-guiding layer, etc.

Active layer 23 is a light-emitting layer disposed above N-side semiconductor layer 22. In the present embodiment, active layer 23 includes a nitride semiconductor and has a quantum well structure. Active layer 23 may include a single quantum well or a plurality of quantum wells. In the present embodiment, active layer 23 includes a plurality of barrier layers containing InGaN and a plurality of well layers containing InGaN.

P-side semiconductor layer 24 is one example of a second semiconductor layer of the second conductivity type which is disposed above active layer 23. P-side semiconductor layer 24 includes a nitride semiconductor. In the present embodiment, P-side semiconductor layer 24 includes a P-type cladding layer having a refractive index lower than the refractive index of active layer 23. P-side semiconductor layer 24 is, for example, a P-type AlGaN layer. Note that P-side semiconductor layer 24 may include a layer other than the P-type cladding layer. P-side semiconductor layer 24 may include, for example, a light-guiding layer, an electron blocking layer, etc. In addition, P-side semiconductor layer 24 may have a superlattice structure.

Ridge 24R is formed in P-side semiconductor layer 24. Ridge 24R is a portion that protrudes in the Z-axis direction within P-side semiconductor layer 24, and extends in the Y-axis direction. In addition, two trenches 24T disposed along ridge 24R and extend in the Y-axis direction are formed in P-side semiconductor layer 24. In the present embodiment, the ridge width (i.e., the dimension of ridge 24R in the X-axis direction) is approximately 30 μm. The dotted lines shown in FIG. 1 correspond to positions of the side faces of trenches 24T (unable to see from the top surface).

Contact layer 25 is disposed above P-side semiconductor layer 24, and in ohmic contact with contact electrode 40. In the present embodiment, contact layer 25 is a P-type GaN layer.

Insulating layer 30 is disposed between semiconductor stack 10S and pad layer 50, and has electrical insulation. Insulating layer 30 includes an opening (or a slit) in the position corresponding to the top surface of ridge 24R. In the present embodiment, insulating layer 30 is disposed, within the top surface of P-side semiconductor layer 24, in the region other than the top surface of ridge 24R. Note that insulating layer 30 may be disposed in a portion of the top surface of ridge 24R. A material to be included in insulating layer 30 is not particularly limited as long as the material is an insulating material. In the present embodiment, insulating layer 30 contains SiO₂.

Adhesion support layer 32 is disposed above insulating layer 30. Adhesion support layer 32 is disposed between insulating layer 30 and pad layer 50, and has a function of increasing the adhesion between pad layer 50 and insulating layer 30. Adhesion support layer 32 includes an opening (or a slit) in the position corresponding to the opening in insulating layer 30. In the present embodiment, the opening in insulating layer 30 is disposed inside the opening in adhesion support layer 32 in the top view of substrate 21. Adhesion support layer 32 may contain at least one of Ti and Cr. When adhesion support layer 32 contains Ti and insulating layer 30 is an oxide, adhesion between adhesion support layer 32 and insulating layer 30 can be increased even more. This is because insulating layer 30 and adhesion support layer 32 strongly bond together when insulating layer 30 is an oxide and adhesion support layer 32 including a metal film is also a material that easily forms an oxide. In the present embodiment, adhesion support layer 32 has a stacked structure including a Ti film disposed on insulating layer 30 and a Pt film disposed on the Ti film.

Contact electrode 40 is disposed above semiconductor stack 10S. Contact electrode 40 faces contact layer 25 above contact layer 25, and is in contact with contact layer 25. In the present embodiment, contact electrode 40 is disposed above ridge 24R. Contact electrode 40 may be, for example, a single-layer film or a multilayer film containing at least one of Ag, Ni, Pd, Cr, and Pt, or a transparent conductive film including a transparent metal oxide, such as an indium tin oxide (ITO), indium zinc oxide (IZO), zinc oxide (ZnO), and InGaZnOₓ (IGZO). In the present embodiment, contact electrode 40 includes a Pd layer in contact with contact layer 25 and a Pt layer disposed above the Pd layer.

Pad layer 50 is disposed above contact electrode 40, and in contact with contact electrode 40. Pad layer 50 contains Au. In the present embodiment, pad layer 50 is a Au layer having thickness of about 4 μm. The detailed configuration of pad layer 50 will be described later.

N-side electrode 60 is a conductive layer disposed on the bottom surface of substrate 21 (i.e., the principal surface of substrate 21 opposite the principal surface of substrate 21 on which semiconductor stack 10S is disposed). N-side electrode 60 is, for example, a single film or multilayer film containing at least one of Cr, Ti, Ni, Pd, and Pt. A pad layer containing Au is formed on N-side electrode 60.

### 1-2. Detailed Configuration and Advantageous Effect of Pad Layer

Next, the detailed configuration and advantageous effects of pad layer 50 according to the present embodiment will be described.

As illustrated in FIG. 2, pad layer 50 includes contact region 51 and external region 52.

Contact region 51 is disposed, within pad layer 50, above the region in which pad layer 50 and contact electrode 40 are in contact with each other. Contact region 51 includes first layer 51a disposed above the region in which pad layer 50 and contact electrode 40 are in contact with each other, and second layer 51b disposed above first layer 51a and in contact with first layer 51a. In the present embodiment, within the region between semiconductor stack 10S and pad layer 50, insulating layer 30 is not disposed in the region between semiconductor stack 10S and first layer 51a.

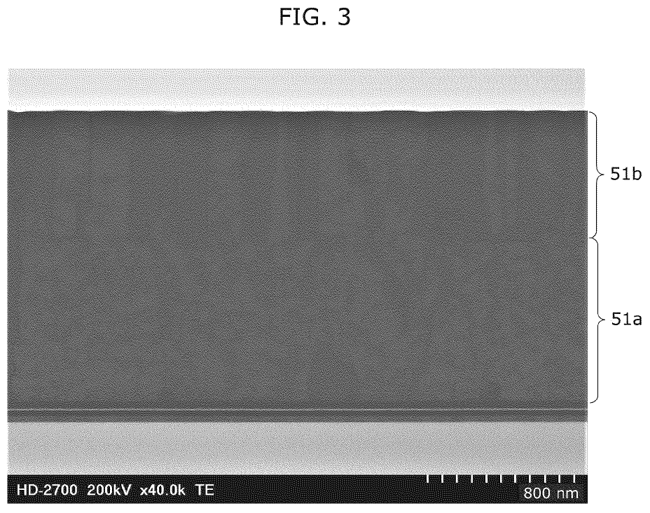

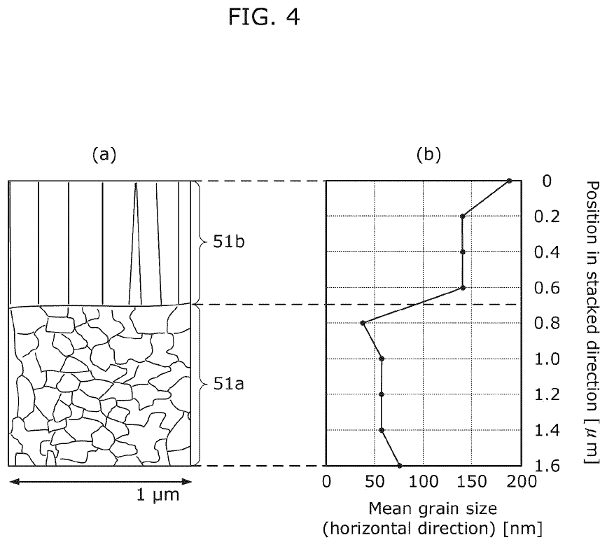

Next, the shapes of crystals in first layer 51a and second layer 51b will be described with reference to FIG. 3 and FIG. 4. FIG. 3 is a transmission electron microscope (TEM) image showing the shapes of crystals in contact region 51 according to the present embodiment. FIG. 3 illustrates the shapes of crystal grains in a cross-section of contact region 51 parallel to the stacked direction of contact region 51. FIG. 4 is a diagram showing the shapes of the crystal grains in contact region 51 according to the present embodiment. FIG. 4 illustrates schematic diagram (a) showing crystal grain boundaries in a cross-section corresponding to the TEM image shown in FIG. 3, and graph (b) showing the distribution of the mean grain sizes in the cross-section corresponding to the TEM image shown in FIG. 3 in the stacked direction. Graph (b) of FIG. 4 shows the mean grain sizes in the direction parallel to a principal surface of contact electrode 40 (i.e., the direction parallel to the XY plane in each diagram). Hereinafter, the direction parallel to the principal surface of contact electrode 40 is also called the “horizontal direction”, and the direction perpendicular to the principal surface of contact electrode 40 is also called the “vertical direction”.

In the present embodiment, first layer 51a is a Au layer having a thickness of about 0.9 μm. As illustrated in FIG. 3 and schematic diagram (a) of FIG. 4, the crystal grains of Au in first layer 51a are the so-called granular whose aspect ratio of the grain size in the horizontal direction to the grain size in the vertical direction is between 0.5 and 2, both inclusive. Second layer 51b is a Au layer having a thickness of about 0.7 μm. As illustrated in FIG. 3 and schematic diagram (a) of FIG. 4, the crystal grains of Au in second layer 51b are columnar. The crystals in second layer 51b extend in the stacked direction (i.e., the Z-axis direction in each diagram). In the horizontal direction, the mean grain size of Au in second layer 51b (i.e., the mean crystal grain size) is larger than the mean grain size of Au in first layer 51a. In the present embodiment, the mean grain size of Au in first layer 51a is about 60 nm in the horizontal direction, and the mean grain size of Au in second layer 51b is about 150 nm in the horizontal direction. Since electrical resistivity is lower for a larger mean grain size of Au, the electrical resistivity of second layer 51b is lower than the electrical resistivity of first layer 51a in the horizontal direction.

The mean value when the direction of the mean grain size of Au in first layer 51a is not specified is about 60 nm, and the mean value when the direction of the mean grain size of Au in second layer 51b is not specified is about 320 nm. Hereinafter, when the direction is not specified, “the mean value when the direction of the mean grain size is not specified” is also simply called “the mean grain size”. A method for measuring the mean grain size of Au will be described later. As has been described above, since the mean grain size of Au in second layer 51b is larger than the mean grain size of Au in first layer 51a, the electrical resistivity of second layer 51b is lower than the electrical resistivity of first layer 51a.

External region 52 illustrated in FIG. 2 is disposed above insulating layer 30 within pad layer 50. In the present embodiment, external region 52 includes a region that is directly connected to (i.e., in contact with) insulating layer 30 and a region that is connected to insulating layer 30 via adhesion support layer 32. In the present embodiment, the shapes of crystal grains of Au in external region 52 are more random than the shapes of crystal grains of Au in first layer 51a. The mean grain size of Au in external region 52 is larger than the mean grain size of Au in first layer 51a, and is smaller than the mean grain size of Au in second layer 51b. In the present embodiment, the mean grain size of Au in external region 52 is about 100 nm.

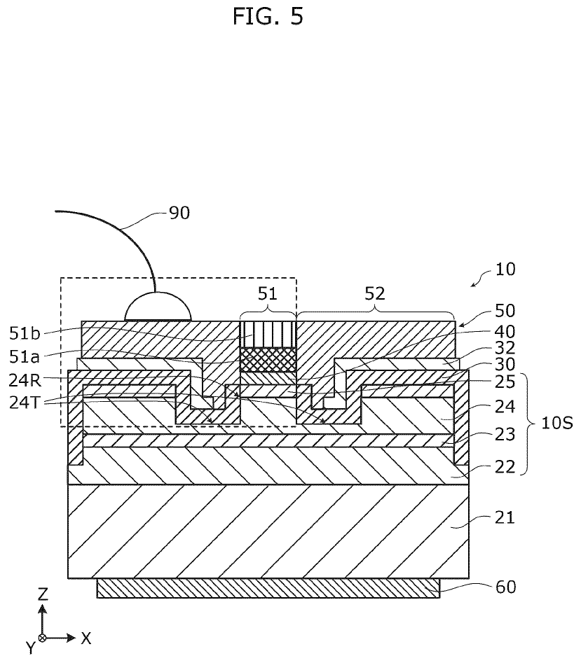

The advantageous effects of pad layer 50 according to the present embodiment will be described in comparison with a comparative example. First, a current supply mode of semiconductor light-emitting element 10 will be described with reference to FIG. 5. FIG. 5 is a diagram illustrating one example of the current supply mode of semiconductor light-emitting element 10 according to the present embodiment.

As illustrated in FIG. 5, a mode of connecting wire 90 to pad layer 50 by bonding can be considered as one example of the current supply mode of semiconductor light-emitting element 10. Wire 90 is a conductive, linear member, and contains, as a conductive material, Au, for example. As illustrated in FIG. 5, wire 90 is arranged, within the top surface of pad layer 50, in a region other than the region above ridge 24R of semiconductor light-emitting element 10, namely, external region 52. With this, it is possible to inhibit damage to ridge 24R and the layers above and below ridge 24R which results from the bonding. Furthermore, in the present embodiment, the shapes of crystal grains of Au in external region 52 are more random than the shapes of crystal grains of Au in first layer 51a, and the mean grain size of Au in external region 52 is larger than the mean grain size of Au in first layer 51a. Accordingly, the hardness of external region 52 is less than the hardness of first layer 51a. In this way, the bonding of wire 90 to external region 52 inhibits damage to semiconductor stack 10S which results from the bonding.

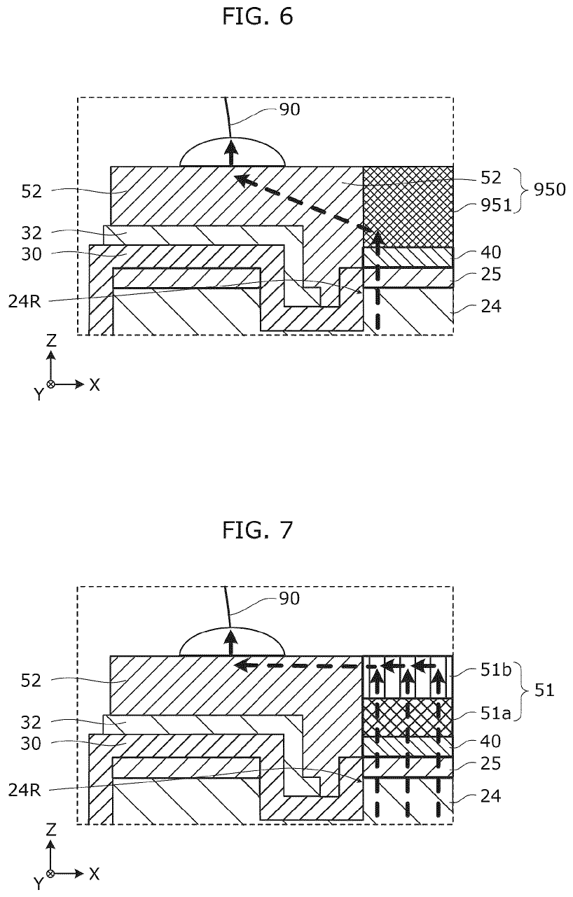

In comparison with a comparative example, current paths in semiconductor light-emitting element 10 when the current supply mode illustrated in FIG. 5 is used will be described with reference to FIG. 6 and FIG. 7. FIG. 6 is a diagram illustrating an overview of the current paths in pad layer 950 of a semiconductor light-emitting element according to the comparative example. FIG. 7 is a diagram illustrating an overview of the current paths in pad layer 50 according to the present embodiment. FIG. 6 and FIG. 7 each illustrate a region corresponding to the inside of the broken-line frame shown in FIG. 5. In FIG. 6 and FIG. 7, dashed-line arrows denote the overview of the paths through which electrons move.

The nitride semiconductor light-emitting element according to the comparative example shown in FIG. 6 is different from semiconductor light-emitting element 10 according to the present embodiment in the configuration of pad layer 950, and agrees with the rest of the configuration of semiconductor light-emitting element 10 according to the present embodiment. Pad layer 950 according to the comparative example includes contact region 951 and external region 52. Contact region 951 according to the comparative example includes crystal grains having the same shapes as the shapes of crystal grains in first layer 51a of contact layer 51 according to the present embodiment. In other words, the crystal grains of Au in contact region 951 are granular. In addition, the mean grain size of Au in contact region 951 according to the comparative example is about 60 nm.

Since the mean grain size of Au in contact region 951 of the semiconductor light-emitting element according to the comparative example is small, the electrical resistivity in contact region 951 is relatively large. For this reason, as illustrated in FIG. 6, electrons move along paths in each of which a distance to pass through contact region 951 is short. In other words, within ridge 24R, the current paths concentrate in a region in the vicinity of the end portion closer to the position at which wire 90 is bonded. Since this causes disproportion in the distribution of light emission intensity in the width direction of ridge 24R of the semiconductor light-emitting element according to the comparative example, deterioration is likely to advance in the vicinity of the peak position of active layer 23 in which the light emission intensity reaches its peak.

Meanwhile, in semiconductor light-emitting element 10 according to the present embodiment, contact region 51 of pad layer 50 includes second layer 51b that is disposed above first layer 51a. Since the mean grain size of Au in second layer 51b in the horizontal direction of second layer 51b is larger than the mean grain size of Au in first layer 51a in the horizontal direction of first layer 51a, the electrical resistivity of second layer 51b in the horizontal direction of second layer 51b is smaller than the electrical resistivity of first layer 51a in the horizontal direction of first layer 51a. In other words, semiconductor light-emitting element 10 according to the present embodiment can reduce the electrical resistance of an electrode including pad layer 50 more than the electrical resistance of an electrode according to the comparative example can be reduced. In this way, electrons in second layer 51b can easily move in the horizontal direction. Accordingly, as illustrated in FIG. 7, current paths can be separated in the width direction of ridge 24R. In other words, semiconductor light-emitting element 10 according to the present embodiment can render the distribution of light emission intensity in the width direction of ridge 24R uniform. Accordingly, the advance of a local deterioration in active layer 23 can be inhibited.

Furthermore, since the crystal grains of Au in second layer 51b are columnar that extends in the stacked direction in the present embodiment, the electrical resistivity of second layer 51b can also be reduced. Therefore, the electrical resistance of pad layer 50 can even more be reduced.

As has been described above, semiconductor light-emitting element 10 according to the present embodiment can reduce the electrical resistance of the electrode.

### 1-3. Method for Measuring Mean Grain Size

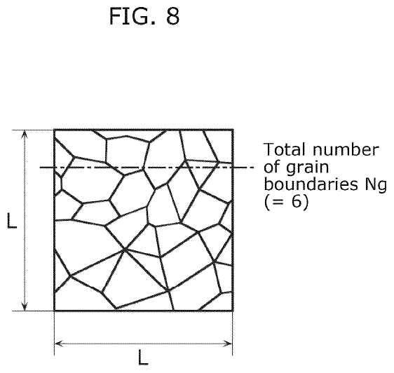

A method for measuring the mean grain size of Au in pad layer 50 will be described with reference to FIG. 8. FIG. 8 is a diagram illustrating a method for measuring the mean grain size. In the present embodiment, after a cross-section of pad layer 50 was formed using the focused ion beam (FIB), the crystal grain sizes were measured by applying the intercept method to an observation region in the scanning ion microscopy image (SIM image) produced by a scanning microscope.

Here, as illustrated in FIG. 8, when, within the square having sides L, Ng crystals having mean crystal size d are present for each side L, the area size of the square is L² and the area size of one crystal grain is n(d/2)². When the observation region is relatively large for the crystal grains, the area size occupied by all of the crystal grains is Ng²×n(d/2)² as there are Ng² crystal grains within the square, and L²=Ng²×n(d/2)² holds true as the area size of the square equals to the region occupied by all of the crystal grains. When the above is expressed in d, the relation d=2L/Ng/(n)^{1/2} holds true. The straight line (dotted-and-dashed line in FIG. 8) was drawn in the observation region L×L using the above relation, and then the mean grain sizes d of pad layer 50 in the horizontal direction and stacked direction were calculated, where the number of grain boundaries intersecting the straight line was determined as the number of crystals, Ng. In FIG. 8, Ng=6, since the straight, dotted-and-dashed line intersects with six grain boundaries. Note that the mean value when the direction of the mean grain size is not specified can be determined by calculating the geometric mean of the mean grain size in the horizontal direction and the mean grain size in the stacked direction.

### 1-4. Manufacturing Method

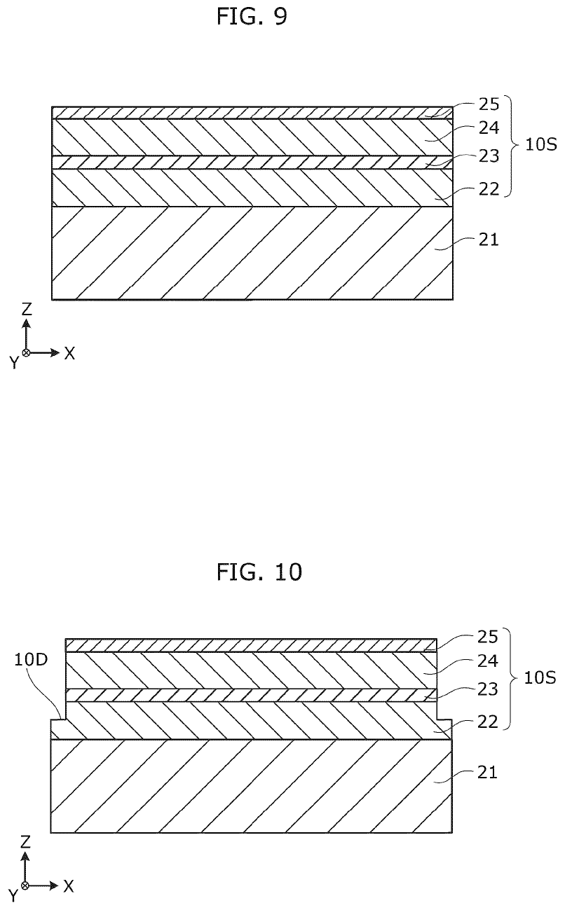

A method for manufacturing semiconductor light-emitting element 10 according to the present embodiment will be described with reference to FIG. 2 and FIG. 9 through FIG. 16. FIG. 9 through FIG. 16 each are a cross sectional view showing a process of the method for manufacturing semiconductor light-emitting element 10 according to the present embodiment. FIG. 9 through FIG. 16 each illustrate a cross-section same as the cross-section shown in FIG. 2.

First, as illustrated in FIG. 9, substrate 21 is prepared. In the present embodiment, a wafer including N-type GaN (GaN substrate) is prepared as substrate 21. Next, using an epitaxial growth technique by the metal organic chemical vapor deposition (MOCVD) method, N-side semiconductor layer 22, active layer 23, P-side semiconductor layer 24, and contact layer 25 are stacked on substrate 21 in the stated order. With this, semiconductor stack 10S can be formed.

Next, as illustrated in FIG. 10, element separation ditches 10D are formed for singulation of semiconductor light-emitting element 10. Element separation ditches 10D are formed in the positions corresponding to both end portions of semiconductor light-emitting element 10 in the X-axis direction. In the present embodiment, element separation ditches 10D each extend from the top surface of semiconductor stack 10S to reach the inside of N-side semiconductor layer 22. The method of forming element separation ditches 10D are not particularly limited. Element separation ditches 10D may be formed using, for example, a photolithographic technique and etching or may be formed by laser machining.

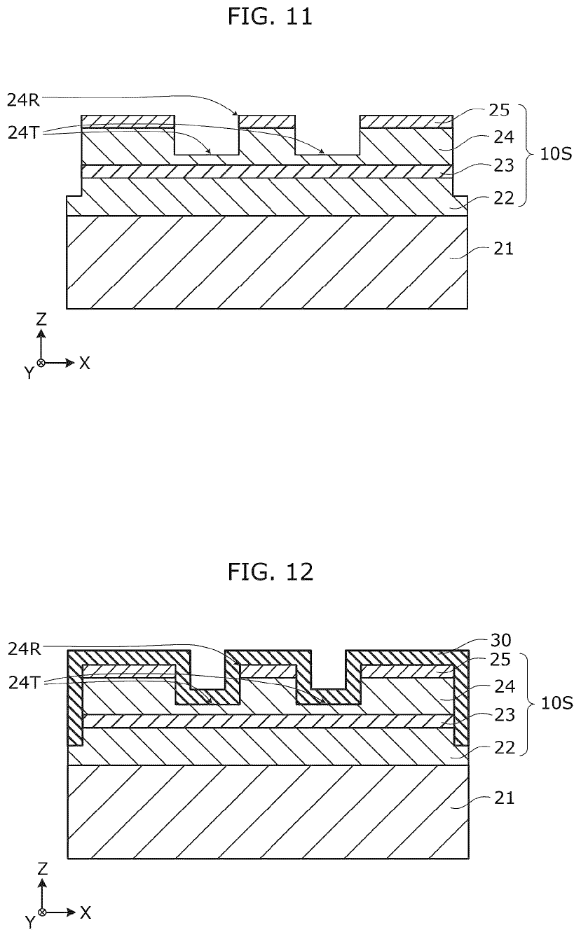

Next, as illustrated in FIG. 11, ridge 24R is formed. In the present embodiment, ridge 24R is formed by forming two trenches 24T in semiconductor stack 10S. Both trenches 24T extend from the top surface of semiconductor stack 10S to reach the inside of P-side semiconductor layer 24. The method of forming trenches 24T are not particularly limited. Trenches 24T may be formed using, for example, a photolithographic technique and etching.

Next, as illustrated in FIG. 12, insulating layer 30 is formed on the top surface of semiconductor stack 10S. In the present embodiment, as insulating layer 30, a SiO₂ film is formed using a plasma chemical vapor deposition (CVD) method or the like. With this, insulating layer 30 including amorphous SiO₂ is formed.

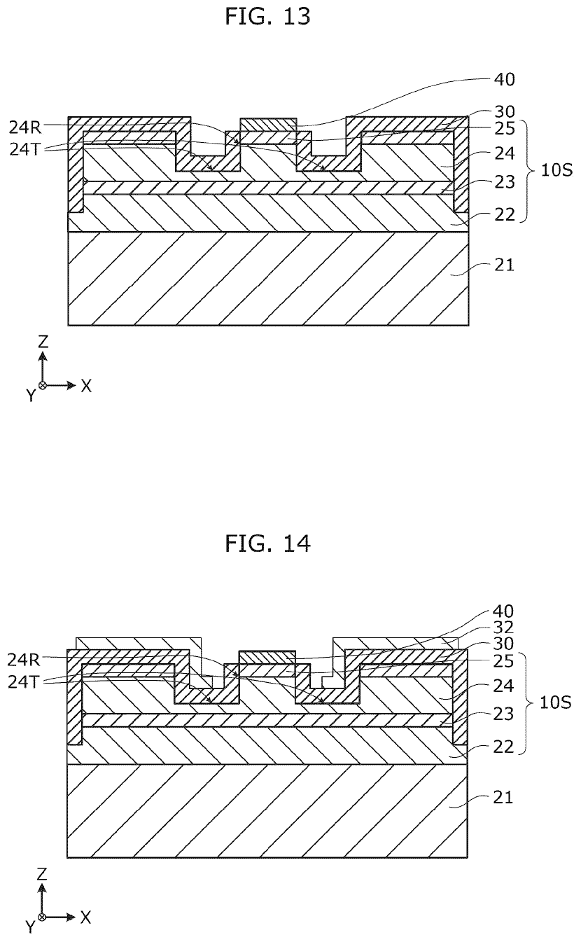

Next, as illustrated in FIG. 13, after insulating layer 30 positioned above ridge 24R is removed using a photolithographic technique and etching, contact electrode 40 is formed on contact layer 25 above ridge 24R. In the present embodiment, a Pd layer and a Pt layer are formed as contact electrode 40. Contact electrode 40 is formed only above ridge 24R using a photolithographic technique and an evaporation method.

Next, as illustrated in FIG. 14, adhesion support layer 32 is formed. More specifically, adhesion support layer 32 including a Ti film and a Pt film is formed above insulating layer 30 using a photolithographic technique and an evaporation method. Since insulating layer 30 is amorphous SiO₂, adhesion support layer 32 includes crystal grains having the shapes more random than the shapes of crystal grains included in a Ti film and a Pt film formed on a monocrystal.

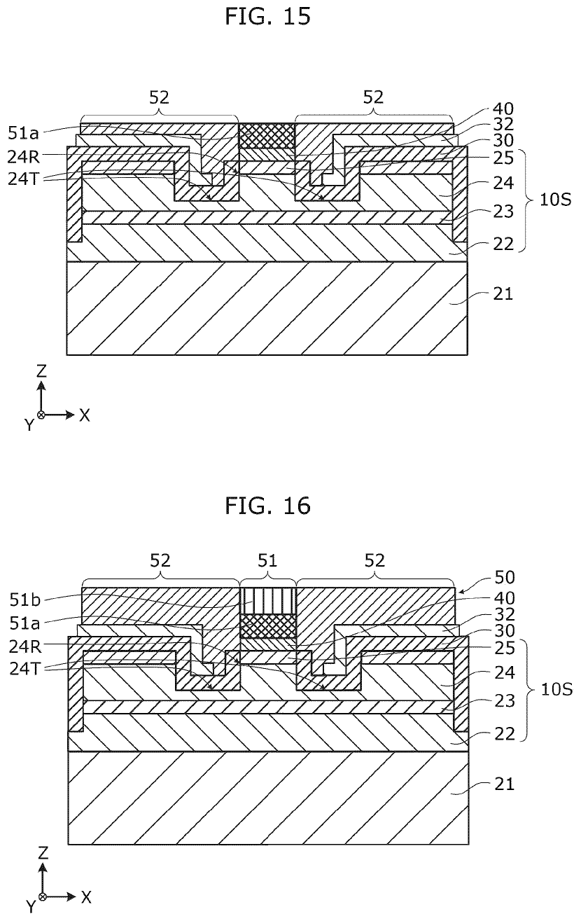

Next, as illustrated in FIG. 15, portions of pad layer 50 are formed. More specifically, a Au film is formed above contact electrode 40 and insulating layer 30 by an evaporation method while maintaining the temperature of substrate 21 at 100° C. With this, first layer 51a including granular, small crystal grains is formed on contact electrode 40. Meanwhile, portions of external region 52 are formed on insulating layer 30 and adhesion support layer 32. Since insulating layer 30 is amorphous SiO₂, external region 52 formed on insulating layer 30 is a Au film that includes crystal grains having random shapes and has many defects such as grain boundaries, etc.

Moreover, since adhesion support layer 32 includes crystal grains having random shapes like the shapes of crystal grains included in insulating layer 30, external region 52 formed on adhesion support layer 32 is also a Au film that includes crystal grains having random shapes and has many defects such as grain boundaries, etc.

Next, as illustrated in FIG. 16, the remaining portion of pad layer 50 is formed. More specifically, after the portions of pad layer 50 as illustrated in FIG. 15 are formed, the formation is suspended to temporarily reduce the temperature of substrate 21 to about 50° C. Next, the formation of a Au film is resumed. The temperature of substrate 21 at this time may rise along with the progress of Au evaporation. With this, Au is epitaxially grown on first layer 51a. Accordingly, it is possible to form second layer 51b that includes columnar crystal grains and has the mean grain size of Au in the horizontal direction of second layer 51b larger than the mean grain size of Au in first layer 51a in the horizontal direction of first layer 51a. In particular, the mean grain size of columnar crystal grains is largest when contact electrode 40 contains Pd.

Next, as illustrated in FIG. 2, N-side electrode 60 is formed on the bottom surface of substrate 21. More specifically, N-side electrode 60 in which a Ti film, a Pt film, and a Au film are formed in the stated order is formed using a photolithographic technique and an evaporation method.

Through the above-described manufacturing method, semiconductor light-emitting element 10 according to the present embodiment can be manufactured.

### Embodiment 2

A light-emitting module according to Embodiment 2 and a manufacturing method thereof will be described. The light-emitting module according to the present embodiment is a module manufactured using the semiconductor light-emitting element according to Embodiment 1.

### 2-1. Overall Configuration

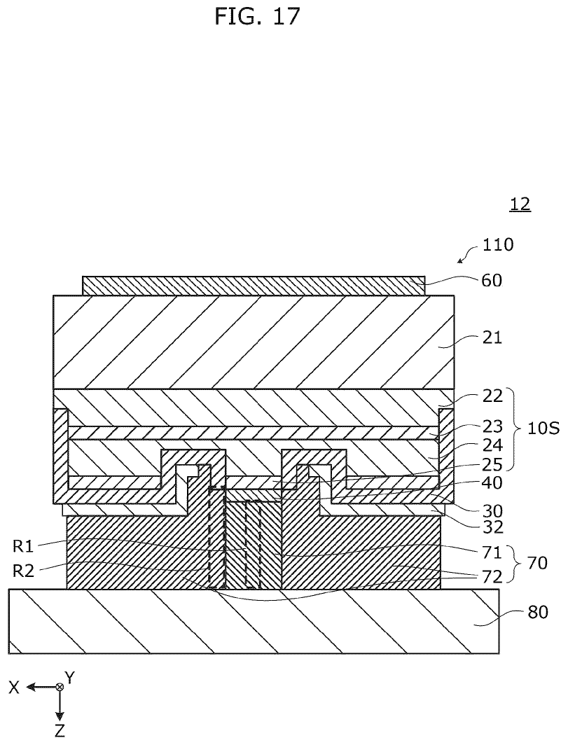

The overall configuration of the light-emitting module according to the present embodiment will be described with reference to FIG. 17. FIG. 17 is a schematic cross-sectional view of the overall configuration of light-emitting module 12 according to the present embodiment.

As illustrated in FIG. 17, light-emitting module 12 includes semiconductor light-emitting element 110 and base 80. Light-emitting module 12 is obtained by junction-down mounting semiconductor light-emitting element 10 according to Embodiment 1 on base 80. A method for manufacturing light-emitting module 12 will be described later.

Base 80 is a member to which semiconductor light-emitting element 110 is joined. In the present embodiment, base 80 is a submount on which semiconductor light-emitting element 110 is mounted. Base 80 is in the shape of a quadrilateral plate. As base 80, a ceramic substrate, a polycrystalline substrate, a monocrystalline substrate, etc., including a material, such as alumina, AlN, SiC, diamond, etc., can be used, for example. Note that base 80 is not limited to a submount. Base 80 may be a mounting substrate on which semiconductor light-emitting element 110 is mounted.

Semiconductor light-emitting element 110 according to the present embodiment include substrate 21, semiconductor stack 10S, contact electrode 40, adhesion support layer 32, joining layer 70, and N-side electrode 60. Semiconductor light-emitting element 110 is different from semiconductor light-emitting element 10 according to Embodiment 1 in that semiconductor light-emitting element 110 includes joining layer 70 instead of pad layer 50. Besides the foregoing difference, semiconductor light-emitting element 110 agrees with semiconductor light-emitting element 10 according to Embodiment 1.

Contact electrode 40 according to the present embodiment is disposed between semiconductor stack 10S and base 80. Insulating layer 30 according to the present embodiment is disposed between semiconductor stack 10S and joining layer 70.

Joining layer 70 is disposed between contact electrode 40 of semiconductor light-emitting element 110 and base 80, and contains AuSn. Joining layer 70 includes first joining region 71 disposed in a position facing contact electrode 40, and second joining region 72 disposed in positions facing insulating layer 30. In the present embodiment, first joining region 71 is also called the inner joining region. In addition, second joining region 72 is also called the outer joining region. In the present embodiment, adhesion support layer 32 is disposed between second joining region 72 and insulating layer 30. Joining layer 70 joins contact electrode 40, insulating layer 30, and adhesion support layer 32 and base 80 together.

### 2-2. Manufacturing Method

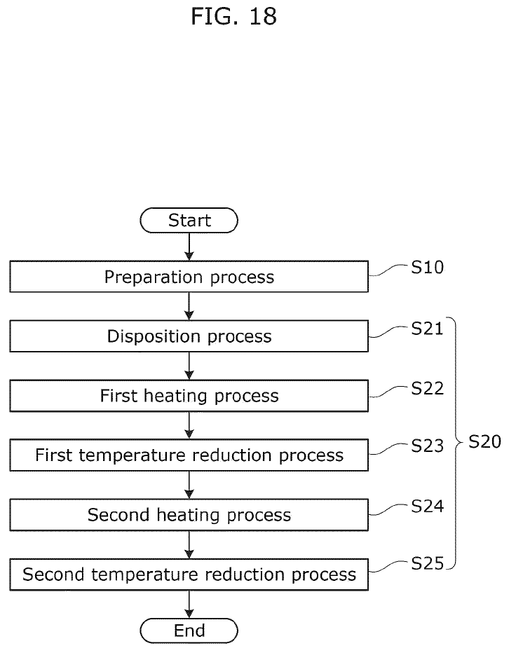

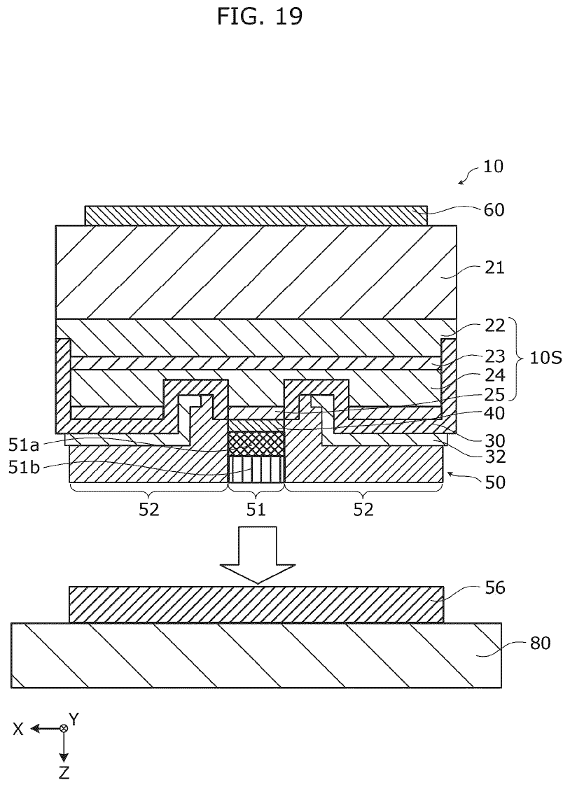

A method for manufacturing light-emitting module 12 according to the present embodiment will be described with reference to FIG. 18 and FIG. 19. FIG. 18 is a flowchart showing a method for manufacturing light-emitting module 12 according to the present embodiment. FIG. 19 is a schematic cross-sectional view showing a preparation process of preparing light-emitting module 12 according to the present embodiment.

First, as illustrated in FIG. 19, semiconductor light-emitting element 10 according to Embodiment 1 and base 80 are prepared (preparation process S10 in FIG. 18). In the present embodiment, joining material 56 is disposed on one principal surface of base 80. In the present embodiment, joining material 56 is a member that joins base 80 and pad layer 50 of semiconductor light-emitting element 10 together in joining process S20 that will be described later. In the present embodiment, joining material 56 is solder containing AuSn.

Next, as illustrated in FIG. 18, semiconductor light-emitting element 10 is joined to base 80 using joining material 56 containing AuSn (joining process S20). Joining process S20 includes disposition process S21, first heating process S22, first temperature reduction process S23, second heating process S24, and second temperature reduction process S25.

In joining process S20, semiconductor light-emitting element 10 is disposed on base 80 in the first place (disposition process S21). More specifically, semiconductor light-emitting element 10 is moved toward base 80 in a state in which pad layer 50 of semiconductor light-emitting element 10 as shown in FIG. 19 is facing joining material 56 disposed on base 80, to bring pad layer 50 of semiconductor light-emitting element 10 into contact with joining material 56 disposed on base 80.

As illustrated in FIG. 18, after disposition process S21, base 80 is heated up to first peak temperature T1 that is higher than melting point Tm of joining material 56 to melt joining material 56 (first heating process S22). More specifically, base 80 is disposed on a heater, and the temperature of the heater is increased to apply heat to base 80. In this first heating process S22, the application of a load to semiconductor light-emitting element 10 is started before the temperature of base 80 reaches melting point Tm of joining material 56 to press semiconductor light-emitting element 10 to base 80. This can increase, after joining material 56 is melted, the contact area size between the surface of semiconductor light-emitting element 10 facing joining material 56 and joining material 56. Stated differently, the formation of a void between semiconductor light-emitting element 10 and joining material 56 can be inhibited.

Next, as illustrated in FIG. 18, after first heating process S22 is performed, the temperature of base 80 is reduced to switching temperature Tv that is a temperature below melting point Tm of joining material 56 (first temperature reduction process S23). In this first temperature reduction process S23, the application of the load to semiconductor light-emitting element 10 is stopped before the temperature of base 80 reaches melting point Tm of joining material 56. The temperature at which the application of the load is stopped need not be higher than melting point Tm, and may be a temperature lower than melting point Tm.

After first temperature reduction process S23 is performed, base 80 is heated up to second peak temperature T2 that is higher than melting point Tm of joining material 56 to melt joining material 56 again (second heating process S24). Here, first peak temperature T1, second peak temperature T2, and melting point Tm of joining material 56 satisfy the relation Tm<T1<T2.

After second heating process S24 is performed, the temperature of base 80 is reduced to a temperature below melting point Tm of joining material 56 (second temperature reduction process S25). Here, the temperature is reduced to a temperature of base 80 before first heating process S22 was performed (i.e., the standby temperature).

During second heating process S24 and second temperature reduction process S25, a load can be applied to semiconductor light-emitting element 10 or need not be applied to semiconductor light-emitting element 10.

Light-emitting module 12 as shown in FIG. 17 can be manufactured according to the above-described processes. In light-emitting module 12, joining layer 70 in which pad layer 50 of semiconductor light-emitting element 10 and joining material 56 are integrated is formed. More specifically, Sn contained in joining material 56 is diffused across pad layer 50 containing Au, and joining layer 70 containing AuSn is formed.

### 2-3. Advantageous Effects

Advantageous effects produced by light-emitting module 12 according to the present embodiment will be described.

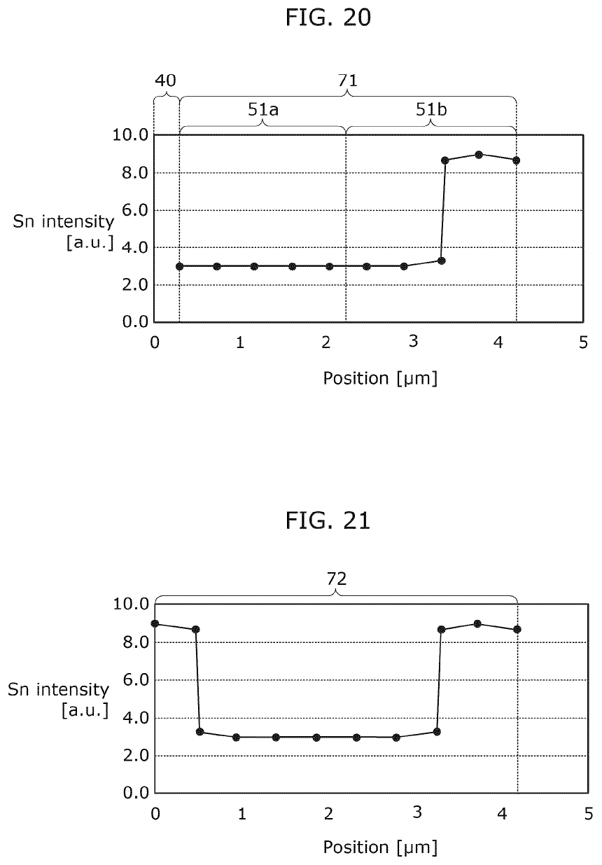

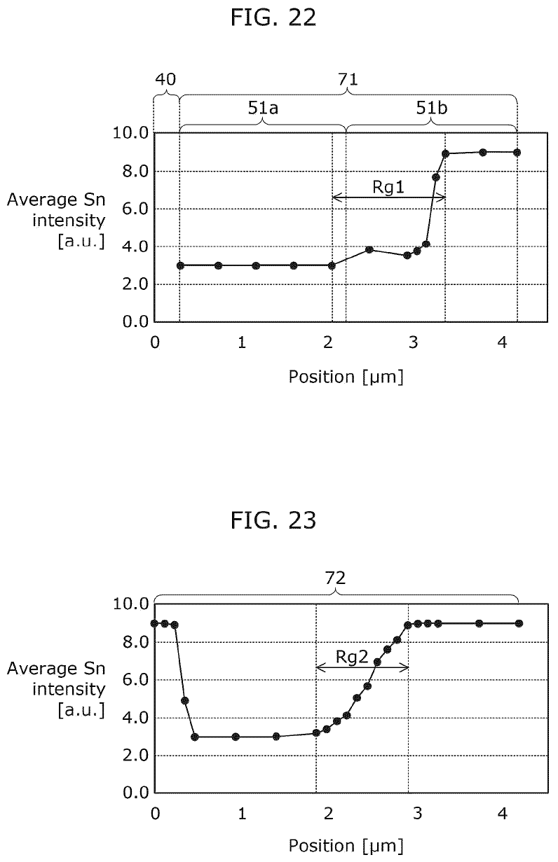

As has been described above, joining layer 70 of light-emitting module 12 according to the present embodiment is a layer in which pad layer 50 of semiconductor light-emitting element 10 according to Embodiment 1 and joining material 56 are integrated. First joining region 71 of joining layer 70 and second joining region 72 of joining layer 70 correspond to contact region 51 of pad layer 50 and external region 52 of pad layer 50, respectively. In other words, first joining region 71 is formed from contact region 51 and a portion of joining material 56, and second joining region 72 is formed from external region 52 and the remaining portion of joining material 56. In accordance with the difference in the shapes of crystal grains between contact region 51 and external region 52, first joining region 71 and second joining region 72 have different Sn distribution states. Hereinafter, the Sn distribution states of first joining region 71 and second joining region 72 will be described with reference to FIG. 20 through FIG. 23. FIG. 20 and FIG. 21 are graphs showing the Sn intensity distribution in first joining region 71 according to the present embodiment and the Sn intensity distribution in second joining region 72 according to the present embodiment, respectively. These Sn intensity distributions were obtained by carrying out energy-dispersive X-ray spectroscopy (EDX) analysis on the straight line along the thickness direction (i.e., the Z-axis direction in each diagram) of first joining region 71 and second joining region 72. FIG. 22 and FIG. 23 are graphs showing the average Sn intensity distribution in first joining region 71 according to the present embodiment and the average Sn intensity distribution in second joining region 72 according to the present embodiment, respectively. These average Sn intensity distributions were obtained by carrying out the EDX analysis on a region along the thickness direction of first joining region 71 and on a region along the thickness direction of second joining region 72. The horizontal axis in each diagram represents positions in the thickness direction. The position approaches base 80 with an increase in the value of the horizontal axis, and the position approaches semiconductor stack 10S with a decrease in the value of the horizontal axis. The average Sn intensity shown in FIG. 22 and the average intensity shown in FIG. 23 are the Sn intensity in the region corresponding to broken-line frame R1 shown in FIG. 17 and the Sn intensity in the region corresponding to broken-line frame R2 shown in FIG. 17, respectively. Broken-line frames R1 and R2 each are a region whose length in the thickness direction of joining layer 70 and length in the X-axis direction of joining layer 70 are both 5 μm. The Sn intensity and average Sn intensity shown in FIG. 20 through FIG. 23 correspond to the Sn content and average Sn content at the position in the thickness direction of joining layer 70.

In the present embodiment, Sn tends to diffuse in the thickness direction in the region corresponding to second layer 51b of pad layer 50 within first joining region 71 of joining layer 70, since the crystal grains of Au are columnar. For this reason, as illustrated in FIG. 20 and FIG. 22, the Sn content of the region corresponding to second layer 51b of pad layer 50 within first joining region 71 is high. As described above, an increase in the Sn content of the region corresponding to pad layer 50 within joining layer 70 can increase bonding strength between joining layer 70 and base 80. Accordingly, detachment of semiconductor light-emitting element 110 from base 80 can be inhibited.

Moreover, as compared to Sn in the region corresponding to second layer 51b, Sn tends not to diffuse in the region corresponding to first layer 51a of pad layer 50 within first joining region 71 of joining layer 70, since Au crystals are granular and the mean grain size of these Au crystals is smaller than the mean grain size of Au in second layer 51b. For this reason, as illustrated in FIG. 20 and FIG. 22, the Sn content of the region corresponding to first layer 51a of pad layer 50 within first joining region 71 is low. Accordingly, as illustrated in FIG. 20, the Sn content of first joining region 71 increases stepwise with an increase in distance from contact electrode 40 on the straight line along the thickness direction of first joining region 71. In addition, as illustrated in FIG. 22, first joining region 71 includes, in the region along the thickness direction of first joining region 71, first transition region Rg1 in which the average Sn content gradually increases with an increase in distance from contact electrode 40. As described above, since an abrupt change in the Sn content in the thickness direction can be inhibited by first joining region 71 including first transition region Rg1 in which the average Sn content gradually increases, an abrupt change in the thermal expansion coefficient in the region in which the Sn content changes can be inhibited. Accordingly, a breakage of first joining region 71 due to a temperature change can be inhibited.

Here, when Sn reaches contact layer 25 via contact electrode 40 that is in contact with first joining region 71, a contact resistance between contact layer 25 and contact electrode 40 increases. However, since the region corresponding to first layer 51a of pad layer 50 within first joining region 71 inhibits the diffusion of Sn in the present embodiment, the diffusion of Sn into contact layer 25 can be inhibited. Accordingly, an increase in the contact resistance between contact layer 25 and contact electrode 40 can be inhibited. In other words, the electrical resistance of an electrode including contact electrode 40 and joining layer 70 of semiconductor light-emitting element 110 can be reduced.

As has been described above, within first joining region 71 in light-emitting module 12 according to the present embodiment, the average Sn content of the region closer to contact electrode 40 than to the center in the thickness direction of first joining region 71 is lower than the average Sn content of the region farther from contact electrode 40 than to the center. Accordingly, an increase in the contact resistance between contact layer 25 and contact electrode 40 can be inhibited.

Second joining region 72 corresponds to external region 52 that has many defects in Au, such as grain boundaries, etc., within pad layer 50. Accordingly, Sn tends to diffuse in second joining region 72. For this reason, as illustrated in FIG. 21 and FIG. 23, a large amount of Sn diffuses up to the end portion of second joining region 72 which is on the side closer to insulating layer 30. With this, bonding strength between joining layer 70 and base 80 can be increased. Accordingly, detachment of semiconductor light-emitting element 110 from base 80 can be inhibited.

Moreover, as illustrated in FIG. 21, the Sn content in the center in the thickness direction of second joining region 72 is lower than the Sn content in the both end portions in the thickness direction of second joining region 72. It is estimated that a high average Sn content, not only in the end portion of second joining region 72 on the base 80 side in the thickness direction of second joining region 72 but also in the end portion on the insulating layer 30 side in the thickness direction of second joining region 72 as described above, results from the local presence of a grain boundary or the local presence of a defect at or in which Sn particularly tends to diffuse in second joining region 72. It is considered that Sn rapidly diffuses, via the local grain boundary or the local defect, from the end portion on the base 80 side in the thickness direction of second joining region 72 to the vicinity of the end portion on the insulating layer 30 side in the thickness direction of second joining region 72, and diffuses in the horizontal direction in the vicinity of the end portion on the insulating layer 30 side. In addition, since a grain boundary or a defect is present only locally in the center in the thickness direction of second joining region 72, it is estimated that the average Sn content in the center in the thickness direction of second joining region 72 would not be so high.

Moreover, as illustrated in FIG. 23, second joining region 72 includes, in the region along the thickness direction of second joining region 72, second transition region Rg2 in which the average Sn content gradually increases with an increase in distance from insulating layer 30. As described above, since an abrupt change in the Sn content in the thickness direction can be inhibited by second joining region 72 including second transition region Rg2 in which the average Sn content gradually increases, an abrupt change in the thermal expansion coefficient in the region in which the Sn content changes can be inhibited. Accordingly, a breakage of second joining region 72 due to a temperature change can be inhibited.

### Variations, etc.

Hereinbefore, the semiconductor light-emitting element, etc., according to the present disclosure have been described based on the above-described embodiments; however, the present disclosure is not limited to these embodiments.

The mean grain size of Au in each of first layer 51a and second layer 51b of pad layer 50 of semiconductor light-emitting element 10 according to Embodiment 1 is not limited to the above-described values. In the horizontal direction, the mean grain size of Au in first layer 51a may be between 30 nm and 80 nm, both inclusive, and the mean grain size of Au in second layer 51b may be between 120 nm and 200 nm, both inclusive. When the direction is not specified, the mean grain size of Au in first layer 51a may be between 30 nm and 80 nm, both inclusive, and the mean grain size of Au in second layer 51b may be between 240 nm and 630 nm, both inclusive.

In addition, although first layer 51a and second layer 51b of pad layer 50 have an approximately equivalent thickness in semiconductor light-emitting element 10 according to Embodiment 1, the relative relationship of thickness between first layer 51a and second layer 51b is not limited to the foregoing. For example, second layer 51b may be thicker than first layer 51a. This increases the proportion of second layer 51b having a smaller electrical resistivity in pad layer 50, thereby reducing the electrical resistivity of pad layer 50.

Moreover, each of the above-described embodiments gives an example in which the semiconductor light-emitting element is a nitride semiconductor laser element, but the semiconductor light-emitting element is not limited to a semiconductor laser element. For example, the semiconductor light-emitting element may be a superluminescent diode. In such cases, the reflectance of the end face of the semiconductor stack included in the nitride semiconductor light-emitting element with respect to the light emitted from the semiconductor stack may be 0.1% or less. For example, such reflectance can be achieved by forming, on the end face, an antireflection film including a dielectric multilayer film, etc. Alternatively, if the ridge that serves as the waveguide has an inclined stripe structure in which the ridge is inclined at an angle of 5° or more from the normal direction of the front-end face to intersect the front-end face, the ratio of the component of guided light reflected off the front-end face that combines with the waveguide and becomes guided light again can be reduced to a small value of 0.1% or less. The semiconductor light-emitting element may further be a light-emitting diode.

Those skilled in the art will readily appreciate that various modifications may be made in these embodiments and that other embodiments may be obtained by optionally combining the elements and functions of the embodiments without materially departing from the novel teachings and advantages of the present disclosure. Accordingly, all such modifications and other embodiments are included in the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The nitride semiconductor light-emitting element, etc., according to the present disclosure can be applied to, for example, a light source for processing machines, as a high-efficiency light source.

1. A semiconductor light-emitting element comprising:
a semiconductor stack;
a contact electrode disposed above the semiconductor stack; and
a pad layer disposed above the contact electrode and containing Au, wherein
the pad layer includes:
a first layer disposed above a region in which the pad layer and the contact electrode are in contact with each other; and
a second layer disposed above the first layer and in contact with the first layer, and
in a direction parallel to a principal surface of the contact electrode, a mean grain size of Au in the second layer is larger than a mean grain size of Au in the first layer.

2. The semiconductor light-emitting element according to claim 1, wherein
a crystal grain of the Au in the second layer is columnar.

3. The semiconductor light-emitting element according to claim 1, further comprising:
an insulating layer disposed between the semiconductor stack and the pad layer, wherein
within a region between the semiconductor stack and the pad layer, the insulating layer is not disposed in a region between the semiconductor stack and the first layer.

4. The semiconductor light-emitting element according to claim 3, wherein
the pad layer includes an external region disposed above the insulating layer, and
a mean grain size of Au in the external region is larger than the mean grain size of the Au in the first layer.

5. The semiconductor light-emitting element according to claim 1, wherein
electrical resistivity of the second layer is lower than electrical resistivity of the first layer.

6. The semiconductor light-emitting element according to claim 1, wherein
the second layer is thicker than the first layer.

7. A light-emitting module comprising:
a semiconductor light-emitting element; and
a base to which the semiconductor light-emitting element is joined, wherein
the semiconductor light-emitting element includes:
a semiconductor stack;
a contact electrode disposed between the semiconductor stack and the base;
a joining layer disposed between the contact electrode and the base, and containing AuSn; and
an insulating layer disposed between the semiconductor stack and the joining layer,
the joining layer includes an outer joining region disposed in a position facing the insulating layer, and
an average Sn content in a center in a thickness direction of the outer joining region is lower than an average Sn content in both end portions in the thickness direction of the outer joining region.

8. The light-emitting module according to claim 7, wherein
the joining layer includes an inner joining region disposed in a position facing the contact electrode, and
within the inner joining region, an average Sn content of a region closer to the contact electrode than to a center in a thickness direction of the inner joining layer is lower than an average Sn content of a region farther from the contact electrode than to the center.

9. The light-emitting module according to claim 8, wherein
a Sn content of the inner joining region increases stepwise with an increase in distance from the contact electrode on a straight line along the thickness direction of the inner joining region.

10. The light-emitting module according to claim 8, wherein
the inner joining region includes a first transition region in which an average Sn content gradually increases with an increase in distance from the contact electrode.

11. The light-emitting module according to claim 7, wherein
the outer joining region includes a second transition region in which an average Sn content gradually changes with an increase in distance from the insulating layer.

12. A method for manufacturing a light-emitting module comprising:
preparing a semiconductor light-emitting element and a base; and
joining the semiconductor light-emitting element to the base, using a joining material containing AuSn, wherein
the semiconductor light-emitting element includes:
a semiconductor stack;
a contact electrode disposed above the semiconductor stack; and
a pad layer electrically connected with the contact electrode, disposed above the contact electrode, and containing Au, the pad layer includes:
a first layer disposed above a region in which the pad layer and the contact electrode are in contact with each other; and
a second layer disposed above the first layer and in contact with the first layer,
a crystal grain of Au in the second layer is columnar,
in a direction parallel to a principal surface of the contact electrode, a mean grain size of the Au in the second layer is larger than a mean grain size of Au in the first layer, and
in the joining, the joining material joins the base and the pad layer together.

13. The method for manufacturing the light-emitting module according to claim 12, wherein
the semiconductor light-emitting element further includes an insulating layer disposed between the semiconductor stack and the pad layer,
in the joining, a joining layer in which the joining material and the pad layer are integrated is formed,
the joining layer includes an outer joining region disposed in a position facing the insulating layer, and
an average Sn content in a center in a thickness direction of the outer joining region is lower than an average Sn content in both end portions in the thickness direction of the outer joining region.

14. The method for manufacturing the light-emitting module according to claim 12, wherein
the semiconductor light-emitting element further includes an insulating layer disposed between the semiconductor stack and the pad layer, and
within a region between the semiconductor stack and the pad layer, the insulating layer is not disposed in a region between the semiconductor stack and the first layer.
